(19) United States
(12) Patent Application Publication
(10) Pub. No.: US 2020/0035299 A1
(43) Pub. Date: Jan. 30, 2020

(54) METHOD AND SYSTEM FOR POWER LOSS PROTECTION

(71) Applicant: Silicon Motion, Inc., Jhubei City (TW)

(72) Inventors: Hung-Lian Lien, Jhubei City (TW); Tsai-Fa Liu, Jhubei City (TW)

(21) Appl. No.: 16/296,241

(22) Filed: Mar. 8, 2019

(30) Foreign Application Priority Data
Jul. 30, 2018 (TW) 107126306

(51) Int. Cl. G11C 13/00; G11C 16/30; G06F 1/3234

(52) U.S. Cl. CPC G11C 13/0069; G06F 1/3275; G11C 16/30

(57) ABSTRACT

A method and system for power loss protection are provided. The method for power loss protection is adapted to a data storage device. The data storage device comprises a controller, a non-volatile memory, a first pin and a second pin. The method for power loss protection comprises the following steps. Firstly, the data storage device receives an operating voltage required for the operation of the data storage device by using the first pin. Then, when a power loss event occurs, the data storage device receives a flash voltage required for the non-volatile memory to write back data by using the second pin, in order that the non-volatile memory completes a data writing procedure.

### FIELD OF THE INVENTION

The present invention relates to a method and a system for power loss protection (PLP), and more particularly to a method and a system for power loss protection for using in a data storage device.

### BACKGROUND OF THE INVENTION

Generally, a method for solving data storage devices, such as a solid-state drive (SSD), in which data is lost due to an abnormal power loss, is to add a power loss protection circuit at the data storage device end, and a large-capacity capacitor in the power loss protection circuit allows the data storage device to obtain an extended power at the moment of the power loss, so that a non-volatile memory in the data storage device, such as a flash memory, can complete a data writing procedure. However, in this type of method, the data storage device also increases its cost by using the large-capacity capacitor, and there is no effective way to provide protection for cached data.

### SUMMARY OF THE INVENTION

In view of the above, an object of the present invention is to provide a method and a system for power loss protection for using in a data storage device. To achieve the above object, an embodiment of the present invention provides a method for power loss protection adapted to a data storage device. The data storage device comprises a controller, a non-volatile memory, a first pin and a second pin. The method for power loss protection comprises the following steps. Firstly, receiving an operating voltage required for the operation of the data storage device by using the first pin; then, when a power loss event occurring, receiving a flash voltage required for the non-volatile memory to write back data by using the second pin, in order that the non-volatile memory completing a data writing procedure.

Additionally, an embodiment of the present invention provides a system for power loss protection. The system for power loss protection comprises a data storage device, and the data storage device comprises a controller, a non-volatile memory, a first pin and a second pin. The first pin is used to receive an operating voltage required for the operation of the data storage device, and when a power loss event occurs, the second pin is used to receive a flash voltage required for the non-volatile memory to write back data, in order that the non-volatile memory completes a data writing procedure.

### BRIEF DESCRIPTION OF THE DRAWINGS

The present invention will become more readily apparent to those ordinarily skilled in the art after reviewing the following detailed description and accompanying drawings, in which:

FIG. 1 is a flowchart of a method for power loss protection according to an embodiment of the present invention;

FIG. 2 is a functional block diagram of a system for power loss protection according to an embodiment of the present invention; and

FIG. 3 is a schematic diagram of an operating voltage and a flash voltage in the system for power loss protection of FIG. 2.

### DETAILED DESCRIPTION OF PREFERRED EMBODIMENTS

In the following, the present invention will be described in detail by various embodiments of the present invention in conjunction with the accompanying drawings. However, the concepts of the present invention may be embodied in many different forms and should not be construed as being limited to the illustrative embodiments set forth herein. In addition, the same reference numerals in the drawings can be used to represent similar elements.

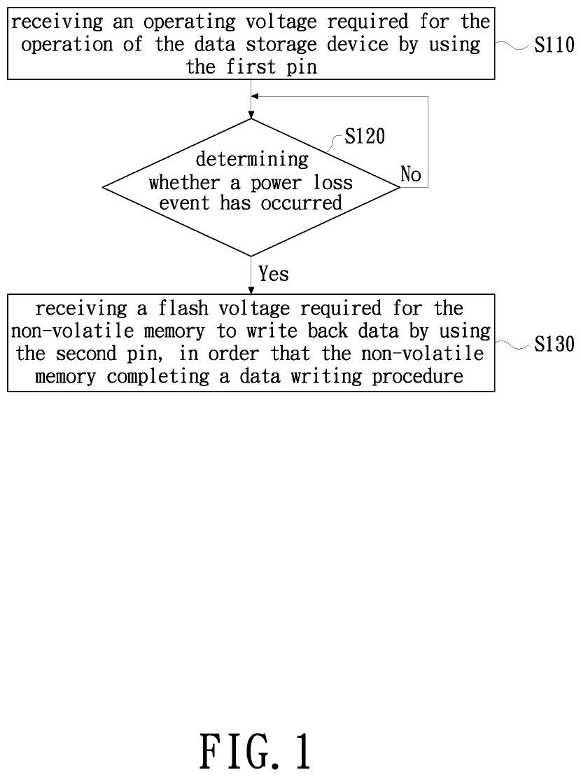

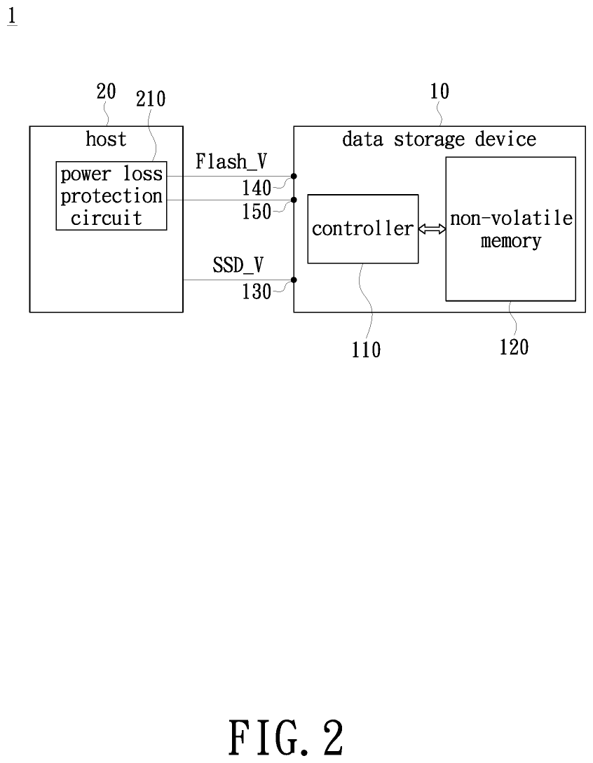

Firstly, please refer to FIG. 1 and FIG. 2 simultaneously. FIG. 1 is a flowchart of a method for power loss protection according to an embodiment of the present invention, and FIG. 2 is a functional block diagram of a system for power loss protection according to an embodiment of the present invention. It should be explained that the method for power loss protection of FIG. 1 can be adapted to a data storage device 10 of FIG. 2, but the present invention does not limit the method for power loss protection of FIG. 1 to be adapted only to the data storage device 10 of FIG. 2.

As shown in FIG. 2, the system for power loss protection 1 comprises the data storage device 10, and the data storage device 10 comprises a controller 110, a non-volatile memory 120, a first pin 130, and a second pin 140. Wherein the controller 110 is electrically coupled to the non-volatile memory 120, and is used to control data access of the non-volatile memory 120. In this embodiment, the data storage device 10 can be implemented, for example, as a solid-state drive, and the non-volatile memory 120 is relatively implemented as a flash memory, but the present invention is not limited thereto.

It should be understood that the data storage device 10 usually receives power required for its operation from the a host 20, and writes data to the non-volatile memory 120 or reads data from the non-volatile memory 120 according to write/read commands issued by the host 20. Therefore, in this embodiment, the system for power loss protection 1 can further comprise the host 20, and the data storage device 10 has a first physical interface (not specifically indicated), and the first physical interface comprises the first pin 130 and the second pin 140. In addition, the host 20 has a second physical interface (not specifically indicated), wherein the first physical interface can be electrically connected to the second physical interface, and used to transmit and receive commands, data, and the like. In this embodiment, both the first physical interface and the second physical interface can be implemented by, for example, an interface such as SATA, PCIE or SAS, but the present invention is not limited thereto. The first pin 130 of the first physical interface is used to receive a power output from the second physical interface, that is, a main power. The main power is used as an operating voltage SSD_V required for the data storage device 10 to operate. And when a power loss event occurs, the second pin 140 of the first physical interface is used to receive a backup power output from the second physical interface, and the backup power is used as a flash voltage Flash_V required for the non-volatile memory 120 to write back data, in order that the non-volatile memory 120 completes a data writing procedure. That is, the first pin 130 of the data storage device 10 is coupled to the host 20 and is used to receive the operating voltage SSD_V provided by the host 20. However, since the backup power is preferably mutually exclusive with the main power, when the host 20 stops providing the main power, in other words, a power loss event occurs, the host 20 provides the flash voltage Flash_V to the data storage device 10 via the second physical interface and the second pin 140 of the first physical interface.

Similarly, in this embodiment, the second pin 140 is preferably coupled to a power loss protection circuit 210 in the host 20, and when a power loss event occurs, the power loss protection circuit 210 in the host 20 is used to provide the flash voltage Flash_V required for the non-volatile memory 120 to write back data. It should be explained that the power loss protection circuit 210 in the host 20 can also be equipped with a large-capacity capacitor (not shown) or placed in an uninterruptible power system (UPS), but the present invention is not limited thereto. In summary, the present invention does not limit the specific implementation manner of the power loss protection circuit 210 in the host 20, and those ordinarily skilled in the art should be able to make related designs according to actual needs or applications. In addition, the flash voltage Flash_V is preferably smaller than the operating voltage SSD_V to help prolong the supply time of the backup power provided by the power loss protection circuit 210, for example, the flash voltage Flash_V is 1.8 volts, and the operating voltage SSD_V is 3.3 volts, but the present invention is not limited thereto.

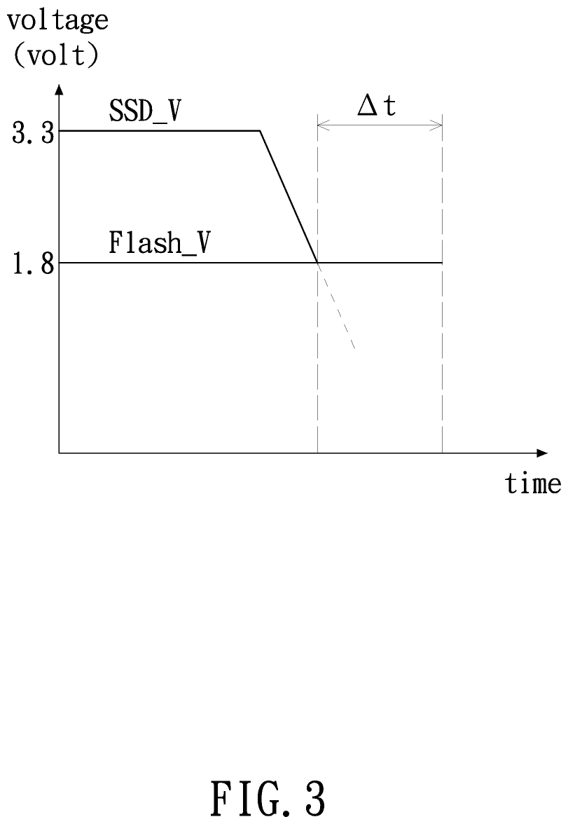

Therefore, when the operating voltage SSD_V provided by the host 20 is maintained at a high potential, the host 20 can use the capacitor in the power loss protection circuit 210 for power storage. Then, when a power loss event occurs, for example, when the operating voltage SSD_V provided by the host 20 drops to a certain low potential, e.g., 1.8 volts, the power loss protection circuit 210 in the host 20 will use the power saved in its capacitor to provide the flash voltage Flash_V for the non-volatile memory 120; thereby enabling the non-volatile memory 120 to maintain an extended period of operation (for example, Δt of FIG. 3) to write back data, and avoiding data loss of the non-volatile memory 120 caused by power loss. According to the teachings of the above, it should be understood by those ordinarily skilled in the art that, the present embodiment is designed to allow the power loss protection circuit 210 to be disposed in the host 20 end, and the power loss protection is directly provided by the host 20 end through the other circuit pin in the data storage device 10, that is, the second pin 140. Therefore, compared to the prior art, the present embodiment can further reduce the cost of the data storage device 10. However, since the operation principles of the data storage device 10 and the host 20 are well known to those of ordinary skill in the art, the details of the above-mentioned contents will not be further described herein.

As described in the foregoing, the controller 110 of the data storage device 10 preferably determines if a power loss event has occurred according to a detection of whether the operating voltage SSD_V received by the first pin 130 is lower than a threshold value. Please refer to FIG. 3 as well for an example. FIG. 3 is a schematic diagram of the operating voltage and the flash voltage in the system for power loss protection of FIG. 2. As shown in FIG. 3, it is assumed that the above threshold value is also 1.8 volts, but the present invention is not limited thereto. Therefore, when the controller 110 detects that the operating voltage SSD_V received by the first pin 130 is lower than 1.8 volts, the data storage device 10 can determine that a power loss event has occurred, and the second pin 140 is used to receive the flash voltage Flash_V provided by the host 20. Alternatively, the power loss protection circuit 210 in the host 20 may also achieve a function to proactively inform the data storage device 10 that a power loss event will occur. Therefore, in this embodiment, the data storage device 10 can further comprise a third pin 150, and the third pin 150 is preferably included in the first physical interface, but the invention is not limited thereto. The third pin 150 is coupled to the power loss protection circuit 210 in the host 20. And when a power loss event occurs, the third pin 150 is used to receive a power loss information (not shown) provided by the power loss protection circuit 210, and the data storage device 10 is caused to use the second pin 140 to receive the flash voltage Flash_V required for the non-volatile memory 120 to write back data.

On the other hand, the data storage device 10 may also transmit other information to the host 20 through the third pin 150, that is, the third pin 150 and the host 20 communicate with each other in both directions. In summary, the present invention does not limit the specific implementation manner of the third pin 150, and those ordinarily skilled in the art should be able to make related designs according to actual needs or applications. Additionally, it should be understood that, in addition to the first pin 130 being the pin required for the original data storage device specification, the present embodiment can use any two redundant pins of the first physical interface in the data storage device 10 to be served directly as the second pin 140 and the third pin 150, thus simplifying the implementation of the present invention. Furthermore, in other embodiments, the second pin 140 of the data storage device 10 can be further modified to continuously receive the flash voltage Flash_V provided by the power loss protection circuit 210 in the host 20 even if a power loss event has not occurred; and when a power loss event occurs, the power loss protection circuit 210 in the host 20 will use the power saved by its capacitor to provide the flash voltage Flash_V to the second pin 140, thereby enabling the non-volatile memory 120 to maintain an extended period of operation to write back data. In summary, this does not affect the implementation of the present invention, and the present invention does not limit the specific implementation manner when the second pin 140 receives the flash voltage Flash_V.

Finally, referring back to FIG. 1, the method for power loss protection of FIG. 1 adapted to the data storage device 10 of FIG. 2 can include the following steps. Firstly, in step S110, the data storage device 10 receives an operating voltage SSD_V required for the operation of the data storage device 10 by using the first pin 130. Secondly, in step S120, the controller 110 of the data storage device 10 determines whether a power loss event has occurred. If yes, step S130 is performed. In step S130, the data storage device 10 receives a flash voltage Flash_V required for the non-volatile memory 120 to write back data by using the second pin 140, in order that the non-volatile memory 120 completes a data writing procedure. Since the details are also as described in the foregoing, they will not be repeated herein.

In summary, the method and the system for power loss protection provided by the embodiments of the present invention can be designed to allow the power loss protection circuit to be disposed in the host end, and the power loss protection is directly provided by the host end through the other circuit pin in the data storage device. Therefore, compared to the prior art, the present embodiment can further reduce the cost of the data storage device.

Note that the specification relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A method for power loss protection (PLP), adapted to a data storage device, the data storage device comprising a controller, a non-volatile memory, a first pin and a second pin, the method for power loss protection comprising following steps of:
receiving an operating voltage required for the operation of the data storage device by using the first pin; and
when a power loss event occurring, receiving a flash voltage required for the non-volatile memory to write back data by using the second pin, in order that the non-volatile memory completing a data writing procedure.

2. The method for power loss protection according to claim 1, wherein the first pin is coupled to a host, and is used to receive the operating voltage provided by the host.

3. The method for power loss protection according to claim 2, wherein the second pin is coupled to a power loss protection circuit in the host, and when the power loss event occurs, the power loss protection circuit in the host is used to provide the flash voltage required for the non-volatile memory to write back data.

4. The method for power loss protection according to claim 3, wherein the controller of the data storage device determines if the power loss event has occurred according to a detection of whether the operating voltage received by the first pin is lower than a threshold value.

5. The method for power loss protection according to claim 3, wherein the data storage device further comprises a third pin, the third pin is coupled to the power loss protection circuit in the host, and when the power loss event occurs, the third pin is used to receive a power loss information provided by the power loss protection circuit, and the data storage device is caused to use the second pin to receive the flash voltage required for the non-volatile memory to write back data.

6. A system for power loss protection, comprising:
a data storage device, comprising:
a controller;
a non-volatile memory;
a first pin; and
a second pin, wherein the first pin is used to receive an operating voltage required for the operation of the data storage device, and when a power loss event occurs, the second pin is used to receive a flash voltage required for the non-volatile memory to write back data, in order that the non-volatile memory completes a data writing procedure.

7. The system for power loss protection according to claim 6, further comprising a host, the first pin coupling to the host, and being used to receive the operating voltage provided by the host.

8. The system for power loss protection according to claim 7, wherein the second pin is coupled to a power loss protection circuit in the host, and when the power loss event occurs, the power loss protection circuit in the host is used to provide the flash voltage required for the non-volatile memory to write back data.

9. The system for power loss protection according to claim 8, wherein the controller of the data storage device determines if the power loss event has occurred according to a detection of whether the operating voltage received by the first pin is lower than a threshold value.

10. The system for power loss protection according to claim 8, wherein the data storage device further comprises a third pin, the third pin is coupled to the power loss protection circuit in the host, and when the power loss event occurs, the third pin is used to receive a power loss information provided by the power loss protection circuit, and the data storage device is caused to use the second pin to receive the flash voltage required for the non-volatile memory to write back data.
